(19) United States
(12) Patent Application Publication
(10) Pub. No.: US 2024/0329117 A1
(43) Pub. Date: Oct. 3, 2024

(54) FAST LEARNING-BASED ELECTROMIGRATION ANALYSIS FOR MULTI-SEGMENT INTERCONNECTS USING A HIERARCHICAL PHYSICS-INFORMED NEURAL NETWORK

(71) Applicant: The Regents of the University of California, Oakland, CA (US)

(72) Inventors: Sheldon X. D. Tan, Irvine, CA (US); Wentian Jin, Moreno Valley, CA (US)

(73) Assignee: The Regents of the University of California, Oakland, CA (US)

(21) Appl. No.: 18/497,886

(22) Filed: Oct. 30, 2023

Related U.S. Application Data
(60) Provisional application No. 63/420,513, filed on Oct. 28, 2022.

(51) Int. Cl. G01R 31/28; G06F 17/13

(52) U.S. Cl. CPC G01R 31/2858; G06F 17/13

(57) ABSTRACT

Described herein is a hierarchical learning-based method, called HierPINN-EM, to solve the Korhonen equations for multi segment interconnects for fast EM failure analysis. HierPINN-EM split the physics laws into two levels and solve the PDE equations step by step. The lower level employs supervised learning to train a DNN model which takes parameterized neurons as inputs and serves as a universal parameterized EM stress solver for single segment wires. The upper level employs physics-informed loss function to train a separate DNN model at the boundaries of all wire segments to enforce the stress and atom flux continuities at internal junctions in interconnects.

### RELATED APPLICATION INFORMATION

This application claims priority from U.S. Provisional Application Ser. No. 63/420,513, entitled “HierPINN-EM: Fast Learning-Based Electromigration Analysis for Multi-Segment Interconnects Using Hierarchical Physics-informed Neural Network”, filed Oct. 28, 2022, the entirety of which is hereby incorporated by reference.

### FIELD OF THE INVENTION

The present invention relates to a fast learning-based electromigration system and method for multi-segment interconnects using a hierarchical physics-informed neural network. More specifically, a learning-based system and method, called Hierarchical PINN or HierPINN-EM framework, is used to solve the Korhonen equations for multi-segment interconnects for fast EM failure analysis.

### BACKGROUND

Electromigration (EM) still remains the primary reliability killer for copper based connects in the current and foreseeable nanometer technology nodes. EM-related aging and other VLSI long-term reliability problems will become worse for current 3 nm and below technologies. Therefore, it is crucial to have an accurate assessment of aging and reliability for both interconnects and devices during the design process.

For EM analysis, it is well known that existing Black and Blech-based EM models are overly conservative and can only work for single wire segment. To mitigate those problems, recently many physics-based EM models and simulation techniques have been proposed. The crux of the problem is to solve Korhonen equations, which is the partial differential equations (PDEs) describing the hydrostatic stress evolution in the confined multi-segment interconnect trees subject to blocking materials boundary conditions. In general, solving the Korhonen equation in particular and PDEs by traditional numerical methods still remains a big challenge due to the inherent limitation of those methods.

Recently, scientific machine learning (SciML) has emerged as a promising and alternative solution to traditional numerical analysis techniques to solve partial differential equations (PDE) due to the breakthrough successes of deep neural networks on cognitive tasks. The main concept is to replace the traditional numerical discretization with a deep neural network (DNN) that approximates the solution of the PDE.

One important framework is so-called physics-informed neural networks (PINN), which use differentiable DNN to regularize the loss functions via back-propagation based training to obtain so-called physics-informed/constrained surrogate models. The resulting models can quickly infer the solutions of the PDE to all input coordinates and parameters. Recently PINN-based EM analysis approach has been proposed in T. Hou, N. Wong, Q. Chen, Z. Ji, and H.-B. Chen, “A space-time neural network for analysis of stress evolution under dc current stressing,” IEEE Transactions on Computer-Aided Design of Integrated Circuits and Systems, pp. 1-1, 2022. The authors show that PINN can be applied to solving the PDE for stress evolution in the confined metal. However, it only demonstrated the solution on the simple interconnect straight wires. Also, the plain PINN method does not work well for large interconnect trees.

### Review of the EM and EM Modeling

EM is a diffusion phenomenon of metal atoms migrating from cathode to anode of confined metal interconnect wires due to the momentum exchange between the conducting electrons and metal atoms. With the EM driving force, the hydrostatic stress increases over time. When the stress reaches a critical value, void is nucleated at the cathode and hillock is created at the anode of the interconnects. This eventually leads to an open or short circuit, which is an EM-induced reliability problem in modern VLSI circuits.

Black's equation predicts EM-induced time-to-failure (TTF) based on an empirical or statistical data fitting, which only works for one specific single wire. Blech's limit, which is an immortality check method, cannot estimate transient hydrostatic stress and is subject to growing criticism due to unnecessary overdesign. To mitigate this problem, the physics-based EM model, Korhonen equations, is employed to describe the hydrostatic stress evolution for general multi-segment interconnects.

The general multi-segment interconnect consists of n nodes, including p interior junction nodes xᵣ∈{xᵣ₁, xᵣ₂, ⋅ ⋅ ⋅ , xᵣₚ} and q block terminals x_{b}∈{x_{b1}, x_{b2}, ⋅ ⋅ ⋅ , x_{bq}} The physics-based Korhonen's PDE for this general structure in nucleation phase can be formulated as follows:

$$\frac{\partial {σ}_{ij} ( x , t )}{\partial t} = \frac{\partial }{\partial x} [ {κ}_{ij} ( \frac{\partial {σ}_{ij} ( x , t )}{\partial x} + {G}_{ij} ) ] , t > 0 \\ BC : {σ}_{{ij}_{1}} ( {x}_{i} , t ) = {σ}_{{ij}_{2}} ( {x}_{i} , t ) , t > 0 \\ BC : {\sum }_{ij} {κ}_{ij} ( \frac{\partial {σ}_{ij} ( x , t )}{\partial x} {\vert}_{x = {x}_{r}} + {G}_{ij} ) \cdot {n}_{r} = 0 , t > 0 \\ BC : {κ}_{ij} ( \frac{\partial {σ}_{ij} ( x , t )}{\partial x} {\vert}_{x = {x}_{b}} + {G}_{ij} ) = 0 , t > 0 \\ IC : {σ}_{ij} ( x , 0 ) = {σ}_{ij , T} \qquad ( 1 )$$

where BC and IC are boundary and initial conditions respectively, ij denotes a branch connected to nodes i and j, nᵣ represents the unit inward normal direction of the interior junction node r on branch ij. σ(x, t) is the hydrostatic stress,

$$G = \frac{{Eq}^{*}}{Ω}$$

is the EM driving force, and κ=DₐBΩ/k_{B}T is the diffusivity of stress. E is the electric field, q* is the effective charge.

$${D}_{a} = {D}_{0} exp ( \frac{- {E}_{a}}{{k}_{B} T} )$$

is the effective atomic diffusion coefficient. D₀ is the pre-exponential factor, B is the effective bulk elasticity modulus, Ω is the atomic lattice volume, k_{B} is the Boltzmann's constant, T is the absolute temperature, Eₐ is the EM activation energy. σ_{T} is the initial thermal induced residual stress.

### Existing Numerical Approaches for Solving PDEs

In order to solve the PDE (equation 1), many conventional numerical and analytical methods are proposed to attempt to solve the PDEs efficiently and accurately. Although the numerical methods, such as finite difference method and finite element method (FEM) can work for the complex interconnect structures and obtain EM stress accurately, they impose high computational costs due to discretization of space and time. Recently, semi-analytical method based on separation of variables method has been proposed, which show promising performance in both accuracy and efficiency on general multi-segment interconnect. Furthermore, an analytic approach was proposed recently, which is very fast. But it cannot be applied to the interconnect line wires.

### Learning Based Approaches for Solving PDEs

Recently machine learning, especially deep learning based on deep neural networks have made breakthrough success in many cognitive applications such as image, text, speech and graph recognition. Inspired by these observations, neural networks are modified to solve the PDEs.

Recently a generative adversarial networks (GAN) based method, called EM-GAN, was proposed to perform a fast transient hydrostatic stress analysis by solving Korhonen equations. It achieved an order of magnitude speedup over the efficient analytic based EM solver with good accuracy. However, this method only works for a fixed region because its output is an image with fixed size, which restricts its application in real chips. What is more, the image is not a natural tool to represent the multi segment interconnects as the region with large areas are filled with nothing. Then Jin et al. further proposed an improved GNN-based EM solver, called EMGraph. Since GNN represents more general and natural relationship among different design objectives, knowledges learned by GNN models tend to be more transferable for different designs, which is highly desirable. However, all those methods are still supervised learning approaches, which requires extensive training from numerical solvers or measured data.

To mitigate this drawback, recently unsupervised learning framework, called physics-informed neural networks, PINN or physics-constrained neural networks have been proposed. The key concept is to frame the PDE solving process into a nonlinear optimization process coded by DNN with the loss functions to enforce the physics laws represented by the PDE and boundary conditions. However, only very simple PDE problems were demonstrated in although some progresses were made for more complicated aerodynamics simulation recently. Recently, a PINN-based approach for EM analysis has been proposed. The method tries to improve the PINN method to better handle the temperature-dependent diffusivities for metal atom migrations. It tries to add more neurons representing some predetermined allocation points and time instances into the neural networks. This method only slightly improves the plain PINN method by achieving better training accuracy at the cost of longer training time under the same number of neurons.

The claimed methods and systems described herein solve problems of the prior art.

### SUMMARY OF THE INVENTION

According to one preferred embodiment, a hierarchical learning-based system and method, called HierPINN-EM, is used to solve the Korhonen equations for multi segment interconnects for fast EM failure analysis. According to another preferred embodiment, the HierPINN-EM splits the physics laws into two levels and solve the PDE equations step by step wherein the lower level employs supervised learning to train a DNN model which takes parameterized neurons as inputs and serves as a universal parameterized EM stress solver for single segment wires; and wherein the upper level employs physics-informed loss function to train a separate DNN model at the boundaries of all wire segments to enforce the stress and atom flux continuities at internal junctions in interconnects.

### BRIEF DESCRIPTION OF THE DRAWINGS

FIG. 1 is a system flow diagram that illustrates a framework of the new stress predictor in the first stage according to one embedment;

FIG. 2 is a system flow diagram of a hierarchical PINN based EM Predictor in a second stage according to one embodiment;

FIG. 3 is a graph illustrating that the predicted stress values all lie close to the red line;

FIGS. 4(a) and 4(b) are graphs illustrating both the worst and best predicted wire segments;

FIGS. 5a and 5b show the comparison of EM stress predicted by HierPINN-EM and ground truth FEM results simulated by COMSOL;

FIGS. 6a and 6b illustrate the comparison of plain PINN and FEM stress results at aging time of 10⁶ s; and

FIGS. 7a and 7b are graphs of the comparison between HierPINN-EM, EM-Graph and COMSOL results of the smallest (10 segments) and largest (105 segments) designs from a test.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, embodiments of the present invention generally provide a new learning-based system and method, called Hierarchical PINN or HierPINN-EM framework, to solve the Korhonen equations for multi-segment interconnects for fast EM failure analysis. The new system and method are as follows:
First shown is the plain PINNbased unsupervised learning does not work very well for interconnects with a large number of segments in terms of accuracy and training speed. To mitigate this problem, disclosed is a new hierarchical PINN solving method to reduce the number of variables, which can lead to faster training and more accurate models. The resulting PINN training framework is called HierPINNEM for fast EM-induced stress analysis for multi-segment interconnects.
In the HierPINN-EM framework, the solving process consists of two steps (levels). The first step is to find a parameterized solution for single-segment wires under different boundary conditions, geometrical parameters and stressing current densities. This step can be solved by different methods. The system provides a supervised learning method to build the DNN model with parameterized input layer as a universal solution to different single-segment wires under various boundary conditions.
In the second step of HierPINN-EM, the system applies the existing unsupervised PINN concept to solve the stress and atom flux continuity problem in the interconnects by enforcing the physics laws at the boundaries of all wire segments. In this way, HierPINN-EM can significantly reduce the number of variables at the PINN solver, which leads to faster training speed and better accuracy than the plain PINN method.
The evaluation results show that HierPINN-EM out performs the plain PINN method in both accuracy and performance with more than 79× error reduction and orders of magnitude speedup, which suggests much better scalability. HierPINN-EM also yields 19% better accuracy with 99% reduction in training cost over the recently proposed state-of-the-art Graph Neural Network (GNN)-based EM solver, EMGraph.

### HierPINN: Hierarchical Physics Informed Neural Network

In more detail, the new hierarchical PINN solving strategy takes multi-segment interconnect tree as input and predicts the EM-induced stress for arbitrary locations in the interconnects at any given aging time. The proposed model solves the stress evolution equations in a hierarchical way which consists of two levels (stages). The first stage, or the lower level, takes only single segment straight wire as input and predicts the stress inside and at both ends of the given wire. The first stage can be viewed as implicitly enforcing the physics laws related to the stress evolution inside a segment wire and leaving the boundaries as the input and output variables to be used in the second stage. The second stage, or the upper level, takes all internal junctions or boundaries as inputs and matches the stress predicted by the lower level at each junction to meet the boundary conditions among adjacent wires (i.e. stress continuity and atom flux conservation) in the original PDE using the PINN optimization framework. Each level employs a multilayer perceptron (MLP) network with different configurations as the backbone.

### Lower Level: Single-Segment Straight Wire Stress Predictor

The lower level of the new hierarchical PINN is a stress predictor/solver which takes single-segment straight wire as input and predicts the EM-induced stress for any location on the wire at a given aging time instant. Multi-segment interconnects always consist of many wire segments with different widths and lengths, stress currents and atomic fluxes at the two terminals. For one wire segment, once the geometrical parameters, current density and boundary conditions are given, EM-induced stresses are determined at all locations including terminals for a given time instant. For one wire segment under those parameterized conditions, one way to obtain the fast and compact model is by means of DNN networks via supervised learning.

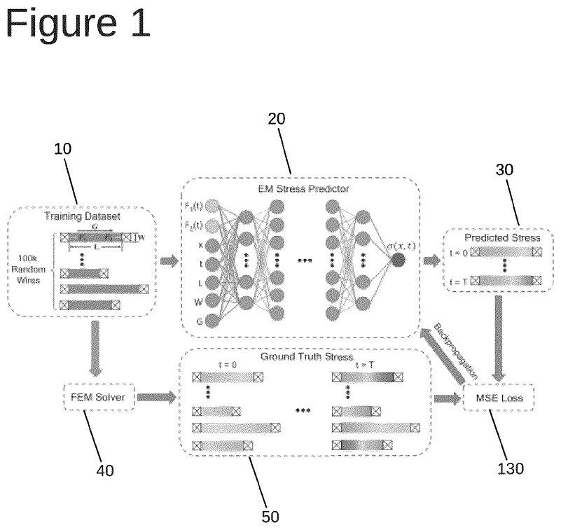

The whole process is illustrated in FIG. 1, which illustrates a framework of the new stress predictor in the first stage. The backbone of the stress predictor is a multilayer perceptron network with 7 layers. The input layer has 7 neurons corresponding to location, aging time, stress current and geometrical parameters of a straight wire. The input vector is called wire feature vector denoted as u. As is shown in FIG. 1, step 10 of the method uses L, W and G to denote the length, width, and driving force of the input wire. F₁ and F₂ are the atom fluxes at left and right end of the wire segment. x and t are the location and aging time at which the stress is to be predicted in step 20. For any input wire, the positive direction of location, driving force and atom flux is always pointing from left to right, such that negative values are allowed to represent the opposite direction. The output layer of stress predictor has only a single neuron with no non-linear activation function attached. The scalar value of this output neuron indicates the predicted stress at the input location x and aging time t, step 30.

For any given combination of wire geometries, driving force and boundary conditions at both ends of a wire, the stress evolution is uniquely determined according to the EM stress PDE. With that being said, at least one task of the stress predictor is to solve the PDE in a single-wire case. The boundary conditions at left and right ends of the wire are defined by F₁ and F₂ respectively, while the rest of the parameters in the stress evolution equation are set by the other 5 input neurons. The input neurons are then processed through layers of non-linear forward propagation operations and the final output neuron is a scalar value indicating the predicted stress. In this process, the stress predictor serves as an approximation to the single-wire EM stress solver. The hidden layers inside the MLP learn to capture the governing physics laws and convert the input features into stress results.

For practical use of this method, the first stage needs to be trained only once (step 10). Then it can be used for different multi-segment wires with different number of wires and topologies and stressing current density conditions. This is a real benefit of the method and system as the training cost of this stage can be ignored for sufficient applications of this method. Further, the method is open to other solving solutions at the first stage (such as analytic solutions, fast numerical solutions). Third, the method can pursue more accurate DNN modeling even at high computing costs.

Regarding the accuracy, the accuracy of stress predictor as an approximated PDE solver is guaranteed in two senses. First, the system may limit the stress predictor to work only on simple single-wire cases instead of overcomplicated interconnect trees. Although a multilayer perceptron, as a universal approximator, can theoretically approximate any complicated non-linear solver, it is not practical to implement it in real cases with limited resources and strict speed requirements. Thus, such limitation substantially reduces the complexity of the problem given to the model, which makes it possible to achieve both high accuracy and performance.

Secondly, the stress predictor is trained on a large dataset consisting of 80k random wires, as is shown in step 10 in FIG. 1. To obtain abundant high-quality training data, the method generated 80k single straight wires and randomly assigned length, width and current density to each wire. These wires are then randomly connected together to create interconnect trees. Due to the randomness in both generation and connection procedures, the resulting interconnect trees are also completely random with various topologies. These interconnects are then passed into COMSOL, which is a commercial FEM solver (step 40), to do the EM stress simulation. The COMSOL-simulated stress evolutions in every single wire, as illustrated at step 50 of FIG. 1, are saved as ground truth results. During the FEM simulation process, the time-variant atom fluxes at both ends of each wire (F₁(t) and F₂(t)) were recorded and then concatenated with wire geometries to serve as input features in the training dataset. Again, such one-time training cost does not add significant overall computing cost to the final HierPINN-EM solution as mentioned earlier.

To verify the accuracy of the proposed stress predictor, the system generated another 20k single wires to serve as the test set. These wires were generated using the same methodology as the system used in generating the training dataset. These test data were never seen by the model during the training process and the trained stress predictor showed impressive accuracy on this test set.

### Upper Level: Atom Flux Predictor for all the Wire Segments

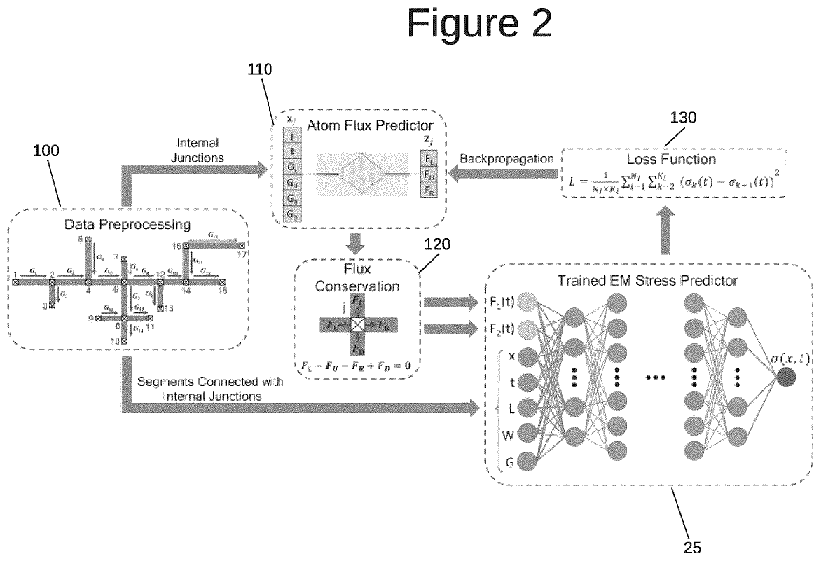

After the lower level stress predictor is trained, the upper level can be added on top of as illustrated in FIG. 2. Similar to the stress predictor 20, the backbone of the upper level is still an MLP but with a completely different objective and configurations.

The goal of the upper level is to predict correct boundary conditions, i.e. atom fluxes, for every single wire in the given interconnect tree, so that the EM stress in internal junctions or boundaries are continuous and EM stress in each wire can be independently derived using the stress predictor already trained in the lower level. To achieve this, an atom flux predictor is implemented using an MLP model with 7 layers.

This model takes internal junctions instead of wire segments as input. Therefore, the first stage in the upper level, as illustrated in step 100 of FIG. 2, is to label all internal junctions in the input interconnect tree starting from 1. Each internal junction is then assigned a feature vector and the feature vector of j-th junction is denoted as xⱼ. The first two entries in the feature vector are the label number j and aging time t. Since each internal junction may have up to 4 wires connected to it from 4 directions, i.e. leftside, upside, rightside, downside, the driving forces were appended in these four directions (G_{L}, G_{U}, G_{R}, and G_{D}) to the feature vector and the driving force would be set to zero if there was no connected wire in the corresponding direction. The resulting feature vectors are then passed into the atom flux predictor, step 110.

The output of atom flux predictor for j-th internal junction is a vector denoted as zⱼ. There are 3 entries in zⱼ, which correspond to the predicted atom fluxes in left, up and right directions respectively. As suggested by the second and third boundary condition in EM PDE (1), the atom fluxes at each internal junction must satisfy the flux conservation law. As a result, in step 120 the flux conservation law is applied to zⱼ to calculate the fourth atom flux in the downward direction using the other three predicted results. In this way, the flux conservation law is strictly enforced at every internal junction in the interconnects. The predicted atom fluxes are then filled into corresponding F₁ and F₂ entries of wire feature vectors u, in which the other entries are directly obtained from the original input interconnects.

A huge advantage of the claimed hierarchical method is that the upper level just requires to be trained at internal junctions instead of the whole interconnects. As a result, the x entries in the wire feature vectors are set to 0 or 1 which corresponds to the left/down or right/up end of each wire separately. This avoids random sampling inside each wire (0<x<1), which would otherwise lead to a large amount of training points and significantly increase the training cost.

The wire feature vectors are then passed into the trained stress predictor, step 25, to obtain the stress results at all internal junctions. For each internal junction at any aging time, there would be 2 to 4 predicted stress results depending on how many wires are connected at this junction. According to the first boundary condition in EM PDE (1), stress values should be continuous at boundaries, which means that the predicted stress results should equal to each other at any internal junction. This leads to the following physics-informed loss function which used to train the atom flux predictor in step 130,

$$L = \frac{1}{{N}_{t} \times {K}_{i}} {\sum }_{i = 1}^{{N}_{t}} {\sum }_{k = 2}^{{K}_{i}} {( {σ}_{k} ( t ) - {σ}_{k - 1} ( t ) )}^{2} \qquad ( 2 )$$

where NI denotes the number of internal junctions in the interconnects, Ki represents the number of connected wires at i-th junction, which ranges between 2 and 4. k(t) is the k-th predicted stress result for the current junction at aging time t. The loss function is the mean squared error (MSE) of all predicted internal junction stress, which serves as a measurement of stress discontinuity at boundaries. When training the upper level, the lower level stress predictor is fixed and the loss is only back-propagated back to the atom flux predictor to update the weights and biases in the model.

The described hierarchical PINN bears some very little similarity to the domain decomposition method in which hierarchical solving strategies are employed. However, there are several distinguished differences between the two approaches. First, in domain decomposition, the subcircuits are typically obtained by partitioning and have to be solved for each subcircuit every time when the whole circuit is to be solved. While for HierPINN-EM, solutions of the single wire, whose boundary or junctions are naturally defined, can be obtained much more efficiently via inference on the DNN network, which only needs to be trained ONCE. At the top level, domain decomposition method tries to solve more dense matrices due to the subcircuit reduction via matrix solving processes like LU decomposition, while HierPINN-EM uses the unsupervised PINN framework to find the solution, which are meshless and easy for design space parameterizations. It uses the differential nature of the DNN model trained in the first stage to guide backpropagation process in the second stage.

### Experimental Results

The system was executed to demonstrate the prediction accuracy, speed and scalability. The HierPINN-EM system and method was tested on both straight wires and interconnect trees that were randomly generated. Both atom flux predictor and stress predictor in HierPINN-EM were implemented in Python 3.8.12 with PyTorch 1.7.1. The training and testing of both models were run on a Linux server with 2 Xeon E5-2699v4 2.2 GHz processors and Nvidia TITAN RTX GPU. In the training phase, Adam optimizer was used to update the model and the learning rate was set to 10⁻⁴. The cross-validation technique was employed in the training process.

### Accuracy of Lower Level on Single-Segment Wires

The lower level stress predictor is the foundation of the described hierarchical method. A 7-layer multilayer perceptron with configurations of [7, 256, 512, 1024, 512, 256, 1] is employed as the backbone of the stress predictor. The stress predictor takes wire feature vector consisting of wire geometries, EM driving force and boundary conditions as input, and outputs the predicted EM-induced stress at given position and aging time. As mentioned above, a large dataset composed of 100k single-segment straight wires were generated, and 80k of them were used to train the model while the rest 20k wires were reserved for testing. The model was trained for 20 epochs which cost approximately 23 hours.

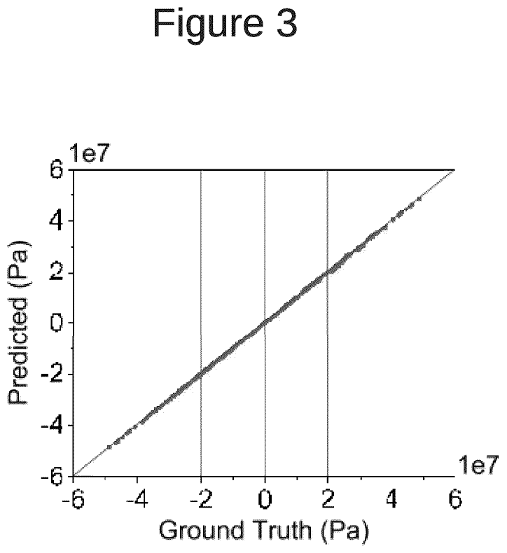

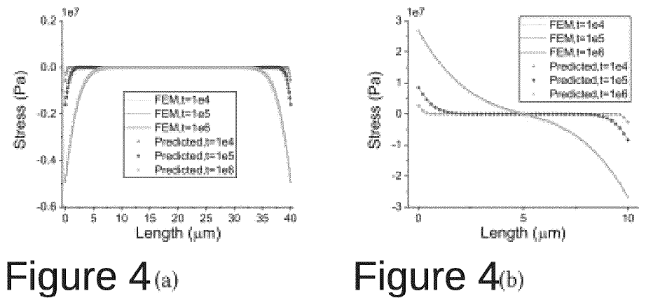

As is shown in FIG. 3, the predicted stress values all lie close to the red line (slope=1, intercept=0). For all 20k wires in the test set, the trained stress predictor yields root-mean-square error (RMSE) from 7.5×10³ to 5.7×10⁴ Pa and achieves an averaged RMSE of 2.7×10⁴ Pa. Both the worst and best predicted wire segments are shown in FIGS. 4a-4b.

The predicted results agree very well with the ground truth even in the worst case, and such accuracy is even more impressive considering that the ground truth stress values vary in a large range between −5×10⁷ and 5×10⁷ Pa. By dividing the RMSE with the full range of the stress (i.e. 10⁸ Pa), the worst and mean error rates of the stress predictor can be calculated as 0.008% and 0.057% separately. Its low error rate in predicting stress in each segment will serve as the foundation of accurate predictions in larger interconnect trees.

It should be noted that this stress predictor only needs to be trained ONCE and can then be embedded into the upper level for EM analysis of different interconnect trees with different topologies. As a result, it can be viewed as a library, which needs to be built once and can actually be generated using different methods as long as the stress evolution physics laws in a single wire are learned and enforced.

### Accuracy of EM Stress Prediction on Straight Wires

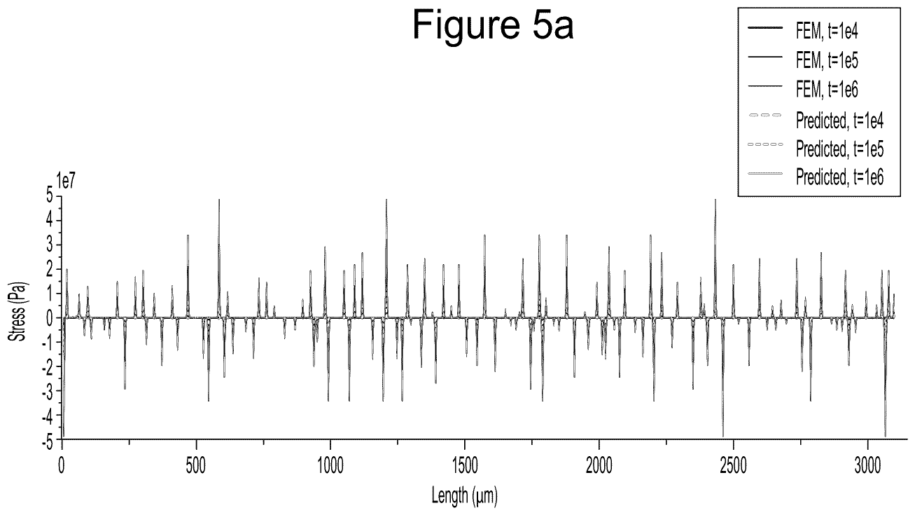

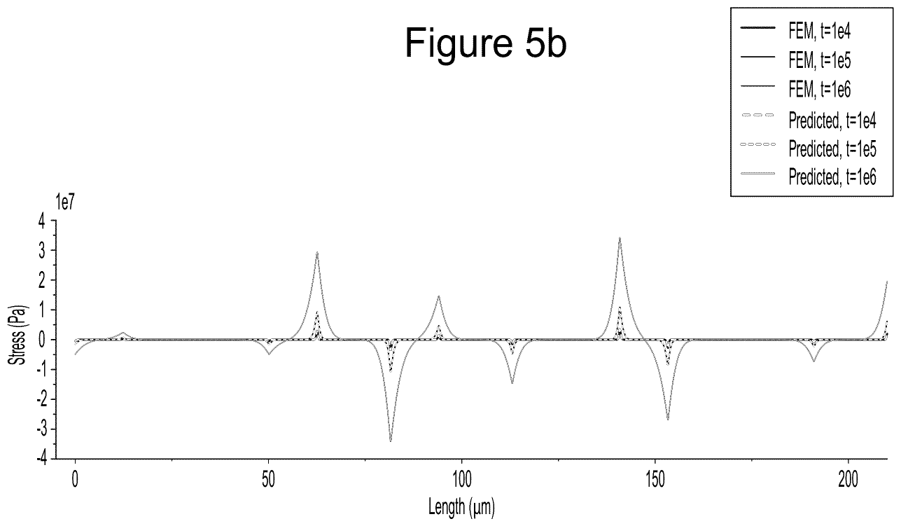

To verify the accuracy of HierPINN-EM, the system was first tested on 121 randomly generated multi-segment straight wires. All test cases have random numbers of segments ranging from 10 to 130. The stressing current density and geometrical parameters of each segment are also randomly assigned. FIGS. 5a and 5b show the comparison of EM stress predicted by HierPINN-EM and ground truth FEM results simulated by COMSOL. FIG. 5(a) shows the results of the smallest case in the test set which has 10 segments, and FIG. 5(b) shows the results of the largest case with 130 segments. To show the evolution of the EM stress as aging time increases, stress results were plotted at three aging time instants (10⁴, 10⁵ and 10⁶ seconds) for each case. The RMSEs of the HierPINN-EM predicted stress results are 5.9×10⁴ and 2.0×10⁵ Pa separately for these two cases. For all 121 test cases, HierPINN-EM yields RMSEs ranging from 4.7×10⁴ to 4.0×10⁵ Pa and the mean error is 1.9×10⁵ Pa which can be converted to 0.19% mean error rate when taking the full 10⁸ Pa stress range into consideration.

To compare HierPINN-EM with existing PINN method, the inventors also implemented a plain PINN model using a 7-layer MLP with exactly the same structure as HierPINN-EM.

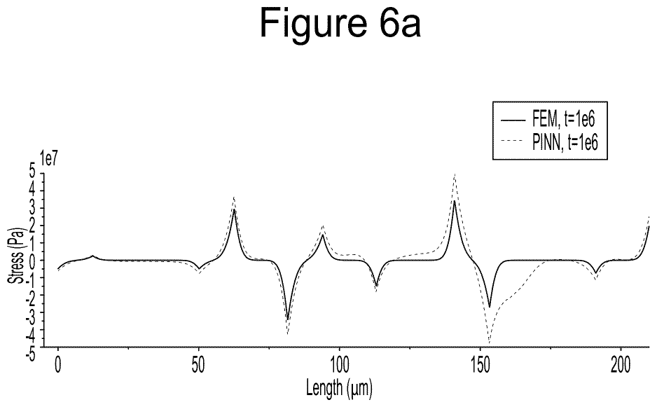

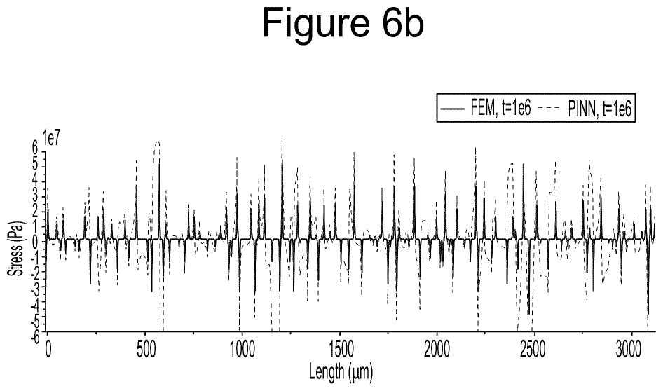

All equations from (1) are formulated into a single physics-informed loss function to train the plain PINN. The inventors tested the plain PINN on the same 10-segment and 130-segment test cases and the comparison of plain PINN and FEM stress results at aging time of 10⁶ s are shown in FIGS. 6a and 6b. The RMSEs of plain PINN results in these two cases are 6.4×10⁶ and 1.6×10⁷ Pa separately, which are 107× and 79× worse than that of HierPINN-EM. Due to the large number of collocation points required in each segment in the training process of the plain PINN model, the training cost is around 30 minutes on the 10-segment case and it leaps significantly to around 10 hours on the 130-segment case. As a comparison, the training costs of HierPINN-EM are only 5.5 s and 39.1 s separately in these two cases. The result verifies the great advantage in scalability of the claimed hierarchical method over the plain PINN model.

The physics-informed loss function used to train the plain PINN model contains all PDE equations for all domains which leads to a complex training process. This means that the PINN model has to be trained simultaneously in all segments and boundaries to minimize every single error in the loss function to satisfy different physics laws. This makes the training process of PINN highly unstable and a successful convergence is not always guaranteed. In contrast, the described HierPINN-EM overcomes this issue by splitting the equations into two levels so that the model at each level is separately trained to satisfy a simpler physics law. The lower level is focused on a single segment while the upper level is based on a trained lower level model, so that the upper level only has to be trained on a few internal junction points which significantly alleviates the training load. Once the upper level is trained, the physics laws inside each segment are automatically satisfied thanks to the highly accurate lower level model which is already shown above.

Moreover, different physics laws in a single loss function also require careful consideration in weight assignment to balance the influence of each equation. Such weight balancing process adds extra overheads to the training process of plain PINN model and further limits its scalability in large interconnects.

### Accuracy of EM Stress Prediction on Interconnect Trees

To demonstrate the generalizability of the proposed model, further tested was HierPINN-EM on 2-D interconnect trees with more complicated topologies. The test set consists of 165 interconnect trees with random numbers of segments ranging from 10 to 105. Similar to the straight wire test set, the stressing current density and geometrical parameters of each segment are also randomly assigned.

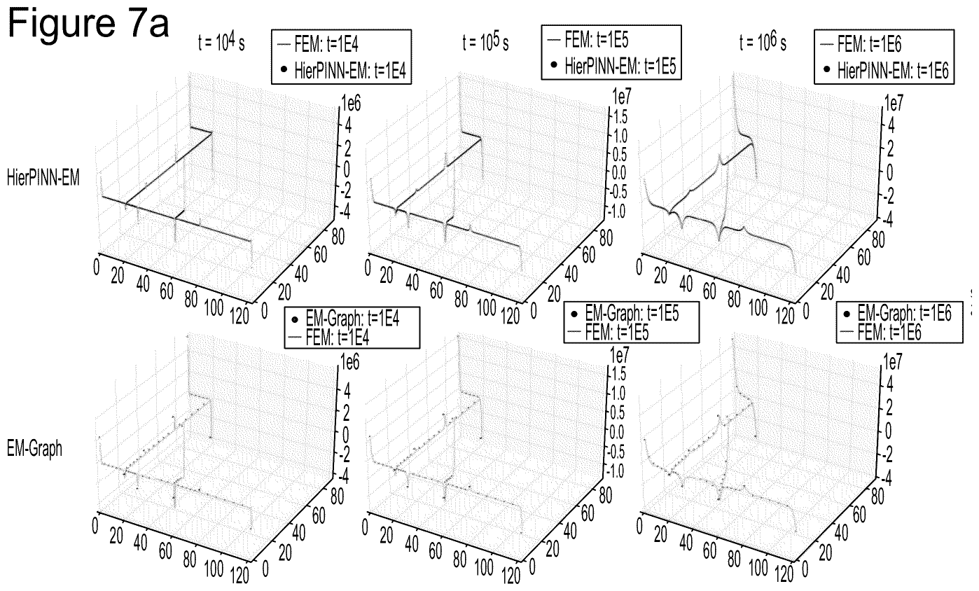

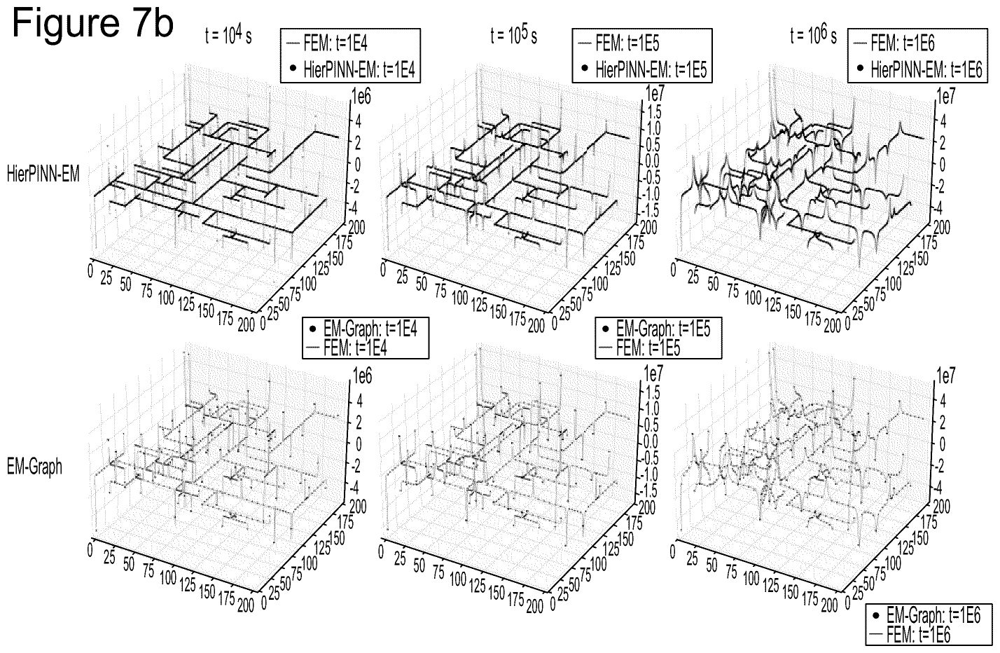

To make an apple-to-apple comparison with GNN-based method EM-Graph, the inventors converted all prediction results into stress maps, which are generated by projecting the predicted stress results for every single segment onto the interconnects topology and are shown in 3-D formats. Shown is the comparison between HierPINN-EM, EM-Graph and COMSOL results of the smallest (10 segments) and largest (105 segments) designs from the test set in FIGS. 7(a) and 7(b). The evolution of the stress at 3 time instants, i.e. 10⁴, 10⁵ and 10⁶ seconds, are illustrated from left to right in each row.

Comparing the predicted stress maps in FIGS. 7(a) and 7(b) with COMSOL ground truth results, HierPINN-EM yields 1.2×10⁵ and 3.4×10⁵ Pa RMSE for these two cases while EM-Graph yields 3.1×10⁵ and 3.9×10⁵ Pa which are slightly worse than HierPINN-EM. For all 165 interconnect trees in the test set, HierPINN-EM achieves better accuracy with a mean RMSE of 2.8×10⁵ Pa while EM-Graph achieves 3.6×10⁵ Pa. Thus, HierPINN-EM outperforms EM-Graph in accuracy with 19% better RMSE when predicting EM-induced stress for 2-D interconnect trees.

Moreover, EM-Graph sets the number of sampling points in each segment to 5 which leads to a coarse granularity in predicted stress results. This is not a big concern when the lengths of segments are relatively small. However, when the segments get much longer, it may introduce huge errors into the prediction since there are large spaces between 5 sampling points and the interpolations between them become much less reliable. This problem is solved in HierPINN-EM as the location input x is a scalar value in float form at which can represent any point in the segment. The granularity of the results can be easily controlled by altering the sampling density of input x. The better inference flexibility gives HierPINN-EM more potential in generalizability to larger interconnect trees.

### Speed of Inference

The training process of the HierPINN-EM is conducted in stages, the lower level was trained for 23 hours, while the training cost of the upper level varies case by case between 4 to 57 seconds, which is mainly determined by the number of internal junctions in the interconnect tree. Although the training of lower level seems quite time-consuming, it only has to be trained ONCE and provides a universal predictor that can be repeatedly used in the upper level with no further tuning effort required.

Once the HierPINN-EM is trained, both levels will be set to inference mode. All sampling points in the interconnects will be passed simultaneously into the model to leverage the parallel computation advantage of GPU. The inventors tested the training and inference speeds of both HierPINN-EM and EM-Graph on the interconnect tree test set, and the results are summarized in Table 1.

| | | | |
|---|---|---|---|
| Metrics | HierPINN-EM | EM-Graph | COMSOL |

| | | | | | |
|---|---|---|---|---|---|
| Max RMSE | 8.9 × 10⁵ | Pa | 5.3 × 10⁵ | Pa | Ground |
| Min RMSE | 8.4 × 10⁴ | Pa | 1.9 × 10⁵ | Pa | Truth |
| Mean RMSE | 2.8 × 10⁵ | Pa | 3.6 × 10⁵ | Pa | |

| | | |
|---|---|---|
| Mean | 0.28% | 0.36% |
| Error Rate | | |

| | | | | | |
|---|---|---|---|---|---|
| Training | <1 | min | 2 | hr | — |
| Speed | | | | | |
| Inference | 0.8 | ms | 0.27 | ms | 30 min |
| Speed | | | | | |

Both learning-based methods are able to achieve magnitudes of speedup against COMSOL. Specifically, the mean inference speed of HierPINN-EM for each interconnect tree is 0.8 ms, which is 3× slower than the 0.27 ms inference speed of EM-Graph. However, such difference in the inference speed is mainly caused by the difference in sampling density as is already shown above. During the inference test, the number of sampling points in each segment varies according to the wire length in HierPINN-EM but is fixed to only 5 in EM-Graph due to its fixed input layer structure. This leads to approximately 30× more sampling points in HierPINN-EM, and thus, more computational cost. However, with such adaptive sampling ability, HierPINN-EM is able to predict more accurate stress map with much better granularity. As a result, the loss in the inference speed is actually an acceptable tradeoff.

Another major advantage of HierPINN-EM over EM-Graph lies in its better flexibility in the inference phase. Limited by the message passing structure of GNN, to predict EM stress in any single segment, the whole interconnect graph requires to be fed into EM Graph so that the target segment can receive useful information from its multi-hop neighbors which can be leveraged to predict stress. This means that EM-Graph is only able to predict stress for interconnects as a whole but is not able to do predictions for small local regions. On the contrary, HierPINN-EM takes position x and time t as input parameters, which enables it to do stress predictions with much better flexibility. It can predict stress for any segment or even a single point in the interconnects at any aging time by simply passing the interested location and time into the model. This enables HierPINN-EM to achieve more significant speedups in local stress analysis. The better accuracy, inference flexibility and results granularity make HierPINN-EM a better learning-based approach for transient EM stress analysis.

Another problem that can be solved is for the post-voiding phase of EM failure process. With the trained hierarchical PINN, the system can predict the EM-induced stress distribution for any interconnect tree at arbitrary aging time during the void nucleation phase. When the stress reaches the critical level, a void is nucleated at the cathode edge of a wire at aging time t_{nuc}. The stress distribution inside the wire can be estimated by the trained stress predictor as σ(x, t_{nuc}) in some embodiments.

Compared to the void nucleation phase, the initial condition of the post-voiding phase is changed to σ(x, t_{nuc}). As a result, the stress predictor for post-voiding phase takes the initial stress distribution as a new input feature in addition to the existing parameterized inputs.

The addition of initial stress as an input feature may be a major challenge for post-voiding phase. Since σ(x, t_{nuc}) is a function of x instead of a singular value like other parameters, it cannot be passed into the MLP model by simply adding an additional input neuron. To solve this problem, one embodiment may use a DeepONet as the backbone of this model. This DNN model can accept a function as inputs as it can model an operator governed by a PDE.

In conclusion, described herein is a hierarchical learning-based method, called HierPINN-EM, to solve the Korhonen equations for multi segment interconnects for fast EM failure analysis. HierPINN-EM split the physics laws into two levels and solve the PDE equations step by step. The lower level employs supervised learning to train a DNN model which takes parameterized neurons as inputs and serves as a universal parameterized EM stress solver for single segment wires. The upper level employs physics-informed loss function to train a separate DNN model at the boundaries of all wire segments to enforce the stress and atom flux continuities at internal junctions in interconnects. Numerical results on a number of synthetic interconnect trees show that HierPINN-EM can lead to orders of magnitude speed up in training and more than 79× better accuracy over the plain PINN method. Furthermore, HierPINNEM yields 19% better accuracy with 99% reduction in training cost over recently proposed Graph Neural Network-based EM solver, EMGraph.

It should be understood, of course, that the foregoing relates to exemplary embodiments of the invention and that modifications may be made without departing from the spirit and scope of the invention as set forth in the following claims.

What is claimed is:

1. A system for fast electromigration (EM) failure analysis, comprising:
a supervised learning module to train a deep neural network (DNN) which takes parameterized neurons as inputs and serves as a universal parameterized EM stress predictor for single segment wires; and
a loss function module to train a separate DNN model at boundaries of all wire segments to enforce stress and atom flux continuities at internal junctions in interconnects.

2. The system of claim 1, wherein the supervised learning module comprises a stress predictor/solver which takes single-segment straight wire as input and predicts the EM-induced stress for any location on the wire at a given aging time instant.

3. The system of claim 1, wherein the supervised learning module comprises multi-segment interconnects comprising a plurality of wire segments with different widths and lengths.

4. The system of claim 1, wherein the supervised learning module comprises multi-segment interconnects comprising a plurality of wire segments with different stress currents and atomic fluxes at two terminals.

5. The system of claim 1, wherein the supervised learning module comprises multi-segment interconnects comprising a plurality of wire segments, wherein for one wire segment, once the geometrical parameters, current density and boundary conditions are given, EM-induced stresses are determined at a plurality of locations including terminals for a given time instant.

6. The system of claim 5, wherein the supervised learning module comprises multi-segment interconnects comprising a plurality of wire segments, wherein for one wire segment under the geometrical parameters, current density and boundary conditions, a of DNN network using supervised learning is used to obtain a fast and compact model.

7. The system of claim 1, further comprising a module that predicts correct boundary conditions all wires in a given interconnect tree.

8. The system of claim 7, wherein an EM stresses in internal junctions or boundaries are continuous.

9. The system of claim 8, wherein the EM stress in each wire is independently derived using the stress predictor.

10. The system of claim 9, further comprising an atom flux predictor implemented using a multilayer perceptron (MLP) model with 7 layers.

11. A method for fast electromigration (EM) failure analysis, comprising:
training a deep neural network (DNN) with a supervised learning module which takes parameterized neurons as inputs and serves as a universal parameterized EM stress predictor for single segment wires; and
training a separate DNN model at boundaries of all wire segments to enforce stress and atom flux continuities at internal junctions in interconnects using a loss function module.

12. The method of claim 11, wherein the supervised learning module comprises a stress predictor/solver which takes single-segment straight wire as input and predicts the EM-induced stress for any location on the wire at a given aging time instant.

13. The method of claim 11, wherein the supervised learning module comprises multi-segment interconnects comprising a plurality of wire segments with different widths and lengths.

14. The method of claim 11, wherein the supervised learning module comprises multi-segment interconnects comprising a plurality of wire segments with different stress currents and atomic fluxes at two terminals.

15. The method of claim 11, wherein the supervised learning module comprises multi-segment interconnects comprising a plurality of wire segments, wherein for one wire segment, once the geometrical parameters, current density and boundary conditions are given, EM-induced stresses are determined at a plurality of locations including terminals for a given time instant.

16. The method of claim 15, wherein the supervised learning module comprises multi-segment interconnects comprising a plurality of wire segments, wherein for one wire segment under the geometrical parameters, current density and boundary conditions, a of DNN network using supervised learning is used to obtain a fast and compact model.

17. The method of claim 11, further comprising a module that predicts correct boundary conditions all wires in a given interconnect tree.

18. The method of claim 17, wherein an EM stresses in internal junctions or boundaries are continuous.

19. The method of claim 18, wherein the EM stress in each wire is independently derived using the stress predictor.

20. The method of claim 19, further comprising implementing an atom flux predictor using a multilayer perceptron (MLP) model with 7 layers.
